(19) United States
(12) Patent Application Publication
(10) Pub. No.: US 2024/0153937 A1
(43) Pub. Date: May 9, 2024

(54) INTERPOSER

(71) Applicant: Murata Manufacturing Co., Ltd., Kyoto-fu (JP)

(72) Inventors: Yoshihito OTSUBO, Nagaokakyo-shi (JP); Yutaka SASAKI, Nagaokakyo-shi (JP)

(21) Appl. No.: 18/417,485

(22) Filed: Jan. 19, 2024

Related U.S. Application Data
(63) Continuation of application No. PCT/JP2022/026704, filed on Jul. 5, 2022.

(30) Foreign Application Priority Data
Jul. 26, 2021 (JP) 2021-121708

(51) Int. Cl. H01L 25/18; H01L 23/00; H01L 23/13; H01L 23/31

(52) U.S. Cl. CPC H01L 25/18; H01L 23/13; H01L 23/3121; H01L 24/32; H01L 2224/32225; H01L 2924/1205; H01L 2924/181

(57) ABSTRACT

An interposer, which has a first surface as a mounting surface, and a second surface where an object is to be mounted, the second surface being opposite the first surface, includes: a first component included in the interposer and having an electrode that is directly exposed on the first surface or is connected to the first surface via a conductor; a second component that is arranged to overlap the first component on a second surface side of the first component and to be in contact with the first component, is included in the interposer, and has an electrode directly exposed on the second surface or connected to the second surface via a conductor; and a sealing resin layer that seals the first component and the second component.

### CROSS REFERENCE TO RELATED APPLICATION

This is a continuation of International Application No. PCT/JP2022/026704 filed on Jul. 5, 2022 which claims priority from Japanese Patent Application No. 2021-121708 filed on Jul. 26, 2021. The contents of these applications are incorporated herein by reference in their entireties.

### BACKGROUND OF THE DISCLOSURE

### Field of the Disclosure

The present disclosure relates to interposers.

### Description of the Related Art

U.S. Pat. No. 10,321,575 B2 (PTL 1) describes an IC module. In PTL 1, an interposer is mounted on the upper surface of a printed circuit board and an IC package is mounted on the interposer. On the lower surface of the interposer, the lower end of a through electrode provided so as to pass through the interposer is exposed, and further, the lower surface of a component included in the interposer is also exposed. Since the thickness of the interposer is larger than the thickness of the included component, an electrode extending in the thickness direction is also provided on the upper side of the included component. A rewiring layer is provided on the upper surface of the interposer. The IC package is provided with a plurality of electrodes and the plurality of electrodes are electrically connected to the rewiring layer.
PTL 1: U.S. Pat. No. 10,321,575 B2

### BRIEF SUMMARY OF THE DISCLOSURE

When a matching circuit arranged on the periphery of an IC or a decoupling capacitor connected to the IC is used and wiring for connection between the IC and the matching circuit or connection between the IC and the decoupling capacitor is long, noise can be mixed into a signal passing through the wiring. It is desirable that such mixing of noise into wiring be avoided as much as possible.

It is also desirable that an interposer include a large number of components inside to achieve high performance. In this case, it is desirable that the large number of components be included in a limited area of the interposer and the thickness of the interposer be made as small as possible.

Accordingly, the present disclosure is aimed at providing an interposer that can include a larger number of components inside while mixing of noise into wiring can be hindered and increase in overall thickness can be avoided.

To achieve the aforementioned aim, an interposer based on the present disclosure, which has a first surface as a mounting surface, and a second surface where an object is to be mounted, the second surface being opposite the first surface, includes: a first component included in the interposer and having an electrode that is directly exposed on the first surface or is connected to the first surface via a conductor; a second component that is arranged to overlap the first component on a second surface side of the first component and to be in contact with the first component, is included in the interposer, and has an electrode directly exposed on the second surface or connected to the second surface via a conductor; and a sealing resin layer that seals the first component and the second component.

According to the present disclosure, an interposer can be attained that can include a larger number of components while mixing of noise into wiring can be hindered and increase in overall thickness can be avoided.

### BRIEF DESCRIPTION OF THE SEVERAL VIEWS OF THE DRAWINGS

FIG. 1 is a cross sectional view of an interposer according to a first embodiment based on the present disclosure, where a coreless substrate is mounted.

FIG. 2 is an explanatory view on a first step in a method for manufacturing the interposer according to the first embodiment based on the present disclosure.

FIG. 3 is an explanatory view on a second step in the method for manufacturing the interposer according to the first embodiment based on the present disclosure.

FIG. 4 is an explanatory view on a third step in the method for manufacturing the interposer according to the first embodiment based on the present disclosure.

FIG. 5 is an explanatory view on a fourth step in the method for manufacturing the interposer according to the first embodiment based on the present disclosure.

FIG. 6 is an explanatory view on a fifth step in the method for manufacturing the interposer according to the first embodiment based on the present disclosure.

FIG. 7 is an explanatory view on a sixth step in the method for manufacturing the interposer according to the first embodiment based on the present disclosure.

FIG. 8 is an explanatory view on a seventh step in the method for manufacturing the interposer according to the first embodiment based on the present disclosure.

FIG. 9 is an explanatory view on an eighth step in the method for manufacturing the interposer according to the first embodiment based on the present disclosure.

FIG. 10 is an explanatory view on a ninth step in the method for manufacturing the interposer according to the first embodiment based on the present disclosure.

FIG. 11 is an explanatory view on a tenth step in the method for manufacturing the interposer according to the first embodiment based on the present disclosure.

FIG. 12 is an explanatory view on an eleventh step in the method for manufacturing the interposer according to the first embodiment based on the present disclosure.

FIG. 13 is a cross sectional view of an interposer according to a second embodiment based on the present disclosure, where a coreless substrate is mounted.

FIG. 14 is a cross sectional view of an interposer according to a third embodiment based on the present disclosure, where a coreless substrate is mounted.

FIG. 15 is a cross sectional view of an interposer according to a fourth embodiment based on the present disclosure, where a coreless substrate is mounted.

FIG. 16 is a cross sectional view of an interposer according to a fifth embodiment based on the present disclosure, where a coreless substrate is mounted.

FIG. 17 is a cross sectional view of an interposer according to a sixth embodiment based on the present disclosure, where a coreless substrate is mounted.

### DETAILED DESCRIPTION OF THE DISCLOSURE

The dimensional ratios in the drawings do not necessarily reflect real ones faithfully but for explanatory convenience, the dimensional ratios may be exaggerated when illustrated. When the concept of up or down orientation is mentioned in the description below, the orientation does not necessarily represent the absolute upper or lower side but a relative upper or lower side in an illustrated position may be implied.

### First Embodiment

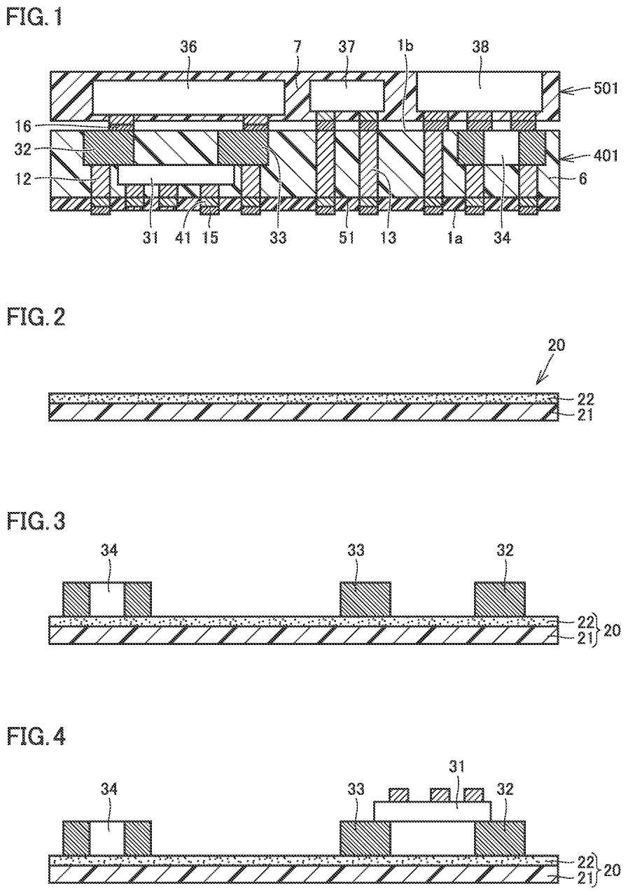

Referring to FIG. 1, an interposer according to a first embodiment based on the present disclosure is described. FIG. 1 presents a cross sectional view of interposer 401 according to the present embodiment, where a coreless substrate 501 is mounted.

Interposer 401 has a first surface 1a as a mounting surface, and a second surface 1b where an object is to be mounted, second surface 1b being opposite first surface 1a. Interposer 401 includes: a first component 31 included in interposer 401 and having an electrode that is directly exposed on first surface 1a or is connected to first surface 1a via a conductor; a second component 32 that is arranged to overlap first component 31 on a second surface 1b side of first component 31 and to be in contact with first component 31, is included in interposer 401, and has an electrode directly exposed on second surface 1b or connected to second surface 1b via a conductor; and a sealing resin layer 6 that seals first component 31 and second component 32. For example, “first surface 1a as a mounting surface” is first surface 1a as a surface for the mounting onto a surface of a motherboard.

Interposer 401 includes for example, components 33 and 34 in addition to first component 31 and second component 32. First component 31 is an IC for example. Second component 32 and components 33 and 34 are capacitors for example. Since second component 32 is in contact with the upper surface of first component 31 but no electrode is provided on the upper surface of first component 31, first component 31 and second component 32 are not connected electrically to each other. The similar applies to component 33. Second component 32 or component 33 is a decoupling capacitor.

Columnar conductors 12 and 13 are arranged in sealing resin layer 6. Columnar conductor 12 electrically connects the lower surface of an electrode of the component and the lower surface of sealing resin layer 6. Columnar conductor 13 electrically connects the upper and lower surfaces of sealing resin layer 6.

First component 31 is provided with an electrode on its lower surface. The electrode may be a solder bump. The electrode on the lower surface of first component 31 is exposed on the lower surface of sealing resin layer 6. A first-surface-side wiring layer 41 is arranged on the lower surface of sealing resin layer 6. The lower surfaces of columnar conductors 12 and 13 are electrically connected to first-surface-side wiring layer 41. The electrode on the lower surface of first component 31 is also electrically connected to first-surface-side wiring layer 41. Although in FIG. 1, a leader line of “41” is given solely to one position as a representative, the portions with the same kind of hatches, which are at this height, are each first-surface-side wiring layer 41. Although first-surface-side wiring layer 41 appears present separately as a plurality of conductor films in the cross sectional view in FIG. 1, part or all of these may extend integrally in positions invisible in the cross section. For example, one first-surface-side wiring layer 41 may be connected to another first-surface-side wiring layer 41 and may be connected to columnar conductor 12 or 13. There may also be components or columnar conductors in positions invisible in the cross section, and thus, first-surface-side wiring layer 41 may be connected thereto. All of first-surface-side wiring layers 41 in single interposer 401 are not necessarily connected electrically in an integrated manner, and the concept called first-surface-side wiring layer 41 may encompass a plurality of wiring units electrically independent of each other.

The lower surface of sealing resin layer 6 is covered by a first-surface-side outer resin layer 51. First-surface-side outer resin layer 51 is a resist layer. First-surface-side wiring layer 41 includes portions covered by first-surface-side outer resin layer 51 and portions not covered by first-surface-side outer resin layer 51. The portions included in first-surface-side wiring layer 41 and not covered by first-surface-side outer resin layer 51 are each covered by a plating film 15.

Second component 32, components 33 and 34, and columnar conductors 13 are exposed on the upper surface of sealing resin layer 6. The respective upper surfaces of second component 32, components 33 and 34, and columnar conductors 13 are coplanar with the upper surface of sealing resin layer 6.

In the present embodiment, the object to be mounted on interposer 401 is coreless substrate 501. Coreless substrate 501 includes components 36, 37, and 38 inside. Components 36, 37, and 38 are sealed with a sealing resin layer 7. Electrodes are provided on the respective lower surfaces of components 36, 37, and 38. The respective electrodes of components 36, 37, and 38 are exposed on the lower surface of coreless substrate 501. The outer surfaces of the respective electrodes of components 36, 37, and 38 are each covered by a plating film 16. The upper surface of component 38 is exposed on the upper surface of coreless substrate 501. Component 36 is an IC for example.

The electrodes covered by plating film 16 on the lower surface of coreless substrate 501 are each connected to interposer 401. This connection is made via solder for example.

In the present embodiment, second component 32 in the interposer is laid on first component 31 and second component 32 is thus positioned close to second surface 1b of the interposer. Accordingly, the wiring for electrical connection from second component 32 to second surface 1b of the interposer can be made considerably short. Consequently, the wiring distance between second component 32 and the object can be made short and mixing of noise can be hindered.

Since in the interposer according to the present embodiment, first component 31 and second component 32 are arranged to overlap each other so as to be in direct contact, a large number of components can be included inside while increase in overall thickness can be avoided.

As mentioned in the present embodiment, in first surface 1a, preferably, first-surface-side outer resin layer 51 is arranged so as to cover sealing resin layer 6, first-surface-side wiring layer 41 is arranged between first-surface-side outer resin layer 51 and sealing resin layer 6, and electrical connection from first component 31 to first surface 1a is made via first-surface-side wiring layer 41. As a result of employing this configuration, the electrode can be exposed on first surface 1a after drawing out the wiring to desired positions in first surface 1a via first-surface-side wiring layer 41 covered up by first-surface-side outer resin layer 51.

As mentioned in the present embodiment, first component 31 is preferably an IC. As a result of employing this configuration, the interposer can have high functionality.

As mentioned in the present embodiment, second component 32 is preferably a capacitor. As a result of employing this configuration, when component 36 included in coreless substrate 501 is an IC, component 36 and second component 32, that is, the IC and the capacitor can be connected with a considerably short distance therebetween. Consequently, the interposer can have high functionality. Although the description here focuses on second component 32 for explanatory convenience, component 33 may be regarded as the second component for example. Component 33 is also preferably a capacitor. In the example illustrated in FIG. 1, component 36 and component 33 can also be connected with a considerably short distance therebetween.

Referring to FIGS. 2 to 12, a method for manufacturing interposer 401 according to the present embodiment is described.

First, a carrier 20 is prepared as illustrated in FIG. 2. Carrier 20 includes a resin layer 21 and an adhesive layer 22 that covers one surface of resin layer 21. Carrier 20 is arranged so that its adhesive layer 22 side faces upward.

As illustrated in FIG. 3, second component 32 and components 33 and 34 are pasted on adhesive layer 22 so as to be in a desired positional relation. Further, as illustrated in FIG. 4, first component 31 is laid on second component 32 and component 33 so as to extend thereon. At this time, first component 31 is joined by a joining member to second component 32 and component 33. The joining member may be an adhesive.

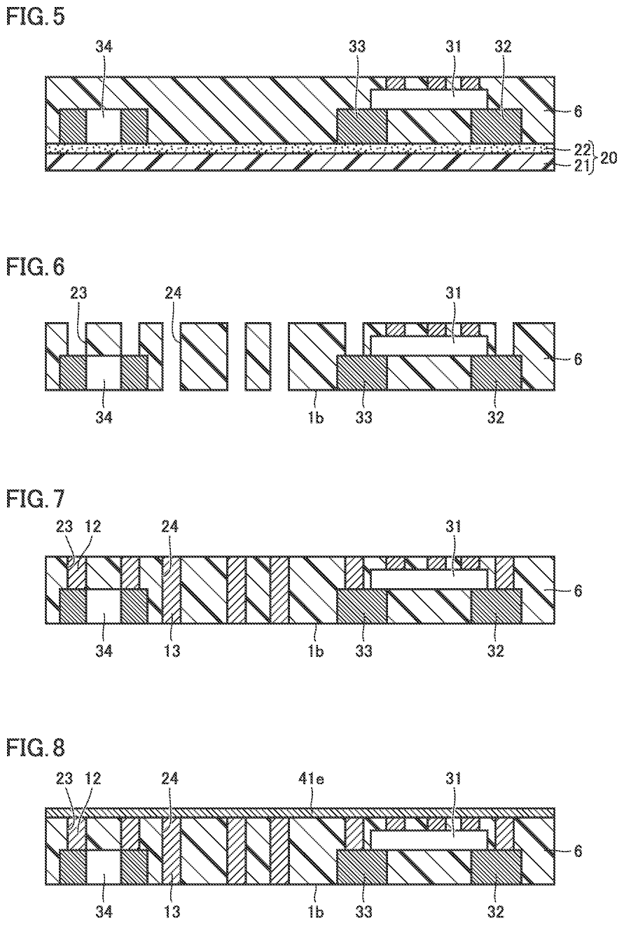

As illustrated in FIG. 5, resin molding is performed. Thus, sealing resin layer 6 is formed. First component 31, second component 32, and components 33 and 34 are covered by sealing resin layer 6. The electrode of first component 31 is exposed from sealing resin layer 6. If necessary, the upper surface of sealing resin layer 6 may be polished. Alternatively, the electrode of first component 31 may be exposed by forming sealing resin layer 6 in advance so that the electrode of first component 31 is hidden, and then polishing the upper surface. After this, carrier 20 is removed.

As illustrated in FIG. 6, boring is performed. Thus, vertical holes 23 and 24 are formed. The boring can be carried out by laser machining for example. Vertical hole 23 reaches the upper surface of component 34. Vertical hole 24 passes through sealing resin layer 6.

As illustrated in FIG. 7, vertical holes 23 and 24 are filled with a metal material. Thus, columnar conductors 12 and 13 are formed. This step may be carried out through plating or be carried out through filling with a conductive paste. When plating is employed, it is simply desired to perform electrolytic plating after pasting a plate material with a conductive outer surface on the lower surface of sealing resin layer 24. The conductive outer surface of the plate material serves as a seed layer.

When columnar conductors 12 and 13 are formed through filling with a conductive paste, the filling may be performed with a certain plate material abutting on the lower surface of sealing resin layer 24.

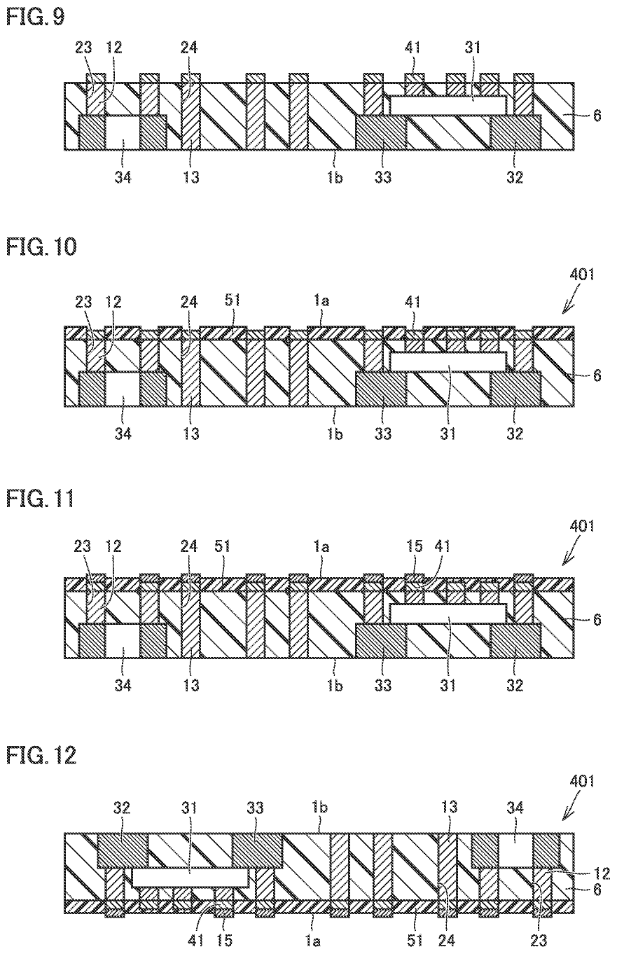

As illustrated in FIG. 8, a metal film 41e is formed so as to cover the upper surface. Metal film 41e may be a Cu film for example. Patterning such as photolithography is performed on metal film 41e, and first-surface-side wiring layer 41 is formed as illustrated in FIG. 9. First-surface-side wiring layer 41 is arranged so as to cover regions in which the upper surfaces of columnar conductors 12 and 13 are exposed on the upper surface of sealing resin layer 6. Although in FIG. 9, first-surface-side wiring layer 41 is illustrated as if it would be present only in these regions, first-surface-side wiring layer 41 may also be formed so as to extend in regions other than these. First-surface-side wiring layer 41 may be wiring made of Cu.

As illustrated in FIG. 10, first-surface-side outer resin layer 51 is formed. First-surface-side outer resin layer 51 is a resist film for example. First-surface-side outer resin layer 51 includes several openings. First-surface-side outer resin layer 51 can be formed by printing. Alternatively, unnecessary portions may be removed after first-surface-side outer resin layer 51 is formed so as to cover the entire surface.

As illustrated in FIG. 11, plating film 15 is formed. The formation of plating film 15 is performed through plating. At this time, interposer 401 is obtained. Plating film 15 may be a multilayer structure made up of a plurality of kinds of plating films. For example, an Ni film may be formed by plating with Ni and after that, an Au film may be formed by plating with Au. In this case, plating film 15 has a double-layer structure including the Ni film and the Au film.

As illustrated in FIG. 12, interposer 401 is turned upside down. The structure illustrated in FIG. 1 can be obtained by mounting coreless substrate 501 on second surface 1b of this interposer 401.

### Second Embodiment

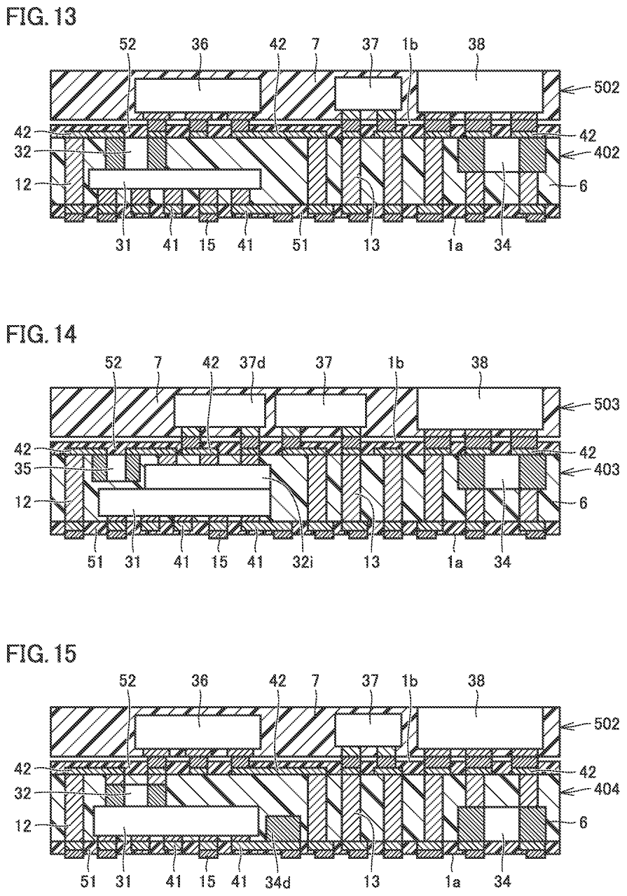

Referring to FIG. 13, an interposer according to a second embodiment based on the present disclosure is described. FIG. 13 presents a cross sectional view of interposer 402 according to the present embodiment, where a coreless substrate 502 is mounted.

Also in respect of interposer 402, the basic configuration is similar to that of interposer 401 described in the first embodiment. However, interposer 402 according to the present embodiment has the following configuration.

In a second surface 1b of interposer 402, a second-surface-side outer resin layer 52 is arranged so as to cover a sealing resin layer 6. A second-surface-side wiring layer 42 is arranged between second-surface-side outer resin layer 52 and sealing resin layer 6. Electrical connection from a second component 32 to second surface 1b is made via second-surface-side wiring layer 42.

Also in the present embodiment, similar advantages to those in the first embodiment can be obtained. As a result of employing this configuration, the electrode can be exposed on second surface 1b after drawing out the wiring to a desired position in second surface 1b via second-surface-side wiring layer 42 covered up by second-surface-side outer resin layer 52. Accordingly, even when the position of the electrode of coreless substrate 502 to be mounted is different from the position of the electrode of interposer 402, efficient electrical connection can be made by using second-surface-side wiring layer 42 to draw out the wiring to a desired position.

In addition, when second component 32 is a decoupling capacitor, second component 32 and a component 36 included in coreless substrate 502 can be connected with a considerably short distance therebetween. Consequently, the interposer can have high functionality. In particular, it is effective when component 36 is an IC.

The similar can apply to a component 34 included in interposer 402. That is, when component 34 is a decoupling capacitor, component 34 and a component 38 included in coreless substrate 502 can be connected with a considerably short distance therebetween. Consequently, the interposer can have high functionality.

### Third Embodiment

Referring to FIG. 14, an interposer according to a third embodiment based on the present disclosure is described. FIG. 14 presents a cross sectional view of interposer 403 according to the present embodiment, where a coreless substrate 503 is mounted.

Also in respect of interposer 403, the basic configuration is similar to that of interposer 401 described in the first embodiment. However, interposer 403 according to the present embodiment has the following configuration.

Interposer 403 includes a second component 32i. Second component 32i is laid on the upper side of a first component 31. In the present embodiment, first component 31 is an IC. In the present embodiment, second component 32i is also an IC. The circuit surface of the IC as first component 31 is in the vicinity of the lower surface of first component 31 in FIG. 14. The circuit surface of the IC as second component 32i is in the vicinity of the upper surface of second component 32i in FIG. 14. Electrodes of first component 31 are in the vicinity of a first surface 1a and are drawn out to first surface 1a via a first-surface-side wiring layer 41. Electrodes of second component 32i are in the vicinity of a second surface 1b and are drawn out to second surface 1b via a second-surface-side wiring layer 42.

Also in the present embodiment, similar advantages to those in the second embodiment can be obtained. In the present embodiment, even in a limited area, high functionality can be given to the interposer by arranging ICs so that the ICs lie on each other. In laying the ICs on each other, the ICs are laid so that the surfaces on the respective opposite sides of the circuit surface sides abut on each other, and thus, the circuit surfaces can lie away from each other. As a result, interference caused by electromagnetic waves between the ICs can be inhibited as much as possible.

### Fourth Embodiment

Referring to FIG. 15, an interposer according to a fourth embodiment based on the present disclosure is described. FIG. 15 presents a cross sectional view of interposer 404 according to the present embodiment, where a coreless substrate 502 is mounted.

Also in respect of interposer 404, the basic configuration is similar to that of interposer 401 described in the first embodiment. However, interposer 404 according to the present embodiment has the following configuration.

Interposer 404 includes components 34 and 34d inside in addition to a first component 31. Component 34 is arranged in the closest position to a first surface 1a, which is in a sealing resin layer 6. A surface of component 34 on the side closer to first surface 1a is exposed from sealing resin layer 6 and this surface is covered by a first-surface-side outer resin layer 51. Component 34d is also arranged in the closest position to first surface 1a, which is in sealing resin layer 6. Component 34d is electrically connected to first component 31 via a first-surface-side wiring layer 41.

Interposer 404 includes a second component 32 inside. Second component 32 is laid on first component 31.

Also in the present embodiment, similar advantages to those described in the first embodiment can be obtained.

### Fifth Embodiment

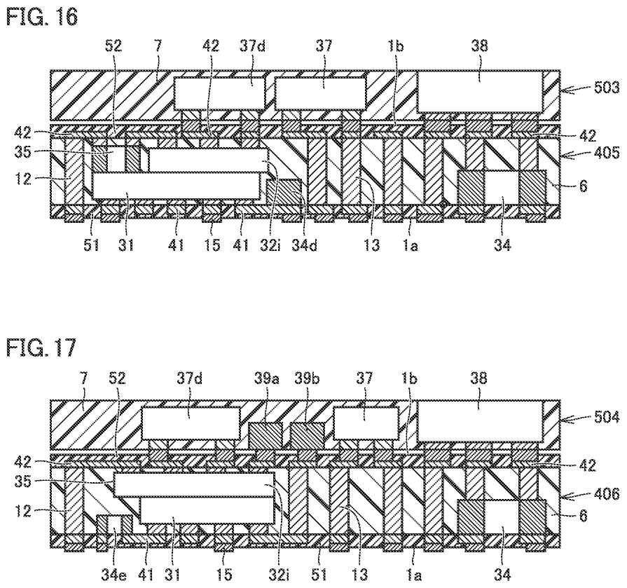

Referring to FIG. 16, an interposer according to a fifth embodiment based on the present disclosure is described. FIG. 16 presents a cross sectional view of interposer 405 according to the present embodiment, where a coreless substrate 503 is mounted.

Also in respect of interposer 405, the basic configuration is similar to that of interposer 404 described in the fourth embodiment. However, interposer 405 according to the present embodiment has the following configuration.

Interposer 405 includes a second components 32i and a component 35 in addition to a first component 31 and components 34 and 34d. First component 31 and second component 32i are both ICs.

Components 34 and 34d are arranged in the closest positions to a first surface 1a in a sealing resin layer 6. Component 34d is electrically connected to first component 31 via a first-surface-side wiring layer 41. Second component 32i is laid on first component 31. Component 35 is also laid on first component 31.

Also in the present embodiment, similar advantages to those described in the fourth embodiment can be obtained.

### Sixth Embodiment

Referring to FIG. 17, an interposer according to a sixth embodiment based on the present disclosure is described. FIG. 17 presents a cross sectional view of interposer 406 according to the present embodiment, where a coreless substrate 504 is mounted.

Also in respect of interposer 406, the basic configuration is similar to that of interposer 405 described in the fifth embodiment. However, interposer 406 according to the present embodiment has the following configuration. Interposer 406 includes a component 34e. Component 34e is arranged in the closest position to a first surface 1a, which is in a sealing resin layer 6. Component 34e is electrically connected to a first component 31 via a first-surface-side wiring layer 41. Electrodes of a second component 32i are partially connected to first surface 1a via a second-surface-side wiring layer 42 and a columnar conductor 13.

Also in the present embodiment, similar advantages to those described in the fifth embodiment can be obtained.

Although each of the above-described embodiments shows an example in which the object to be mounted on second surface 1b of the interposer is a coreless substrate, the object to be mounted is not limited to a coreless substrate. The object to be mounted may be a wiring board or a board with components mounted thereon. For another instance, it may be a single component.

Two or more of the above-described embodiments may be employed by being combined as necessary.

The above-described embodiments in the present disclosure are examples in every respect and are not limiting. The scope of the present disclosure is defined by the claims and includes all changes within the purport and scope equivalent to the claims.

1a first surface; 1b second surface; 6, 7 sealing resin layer; 12, 13 columnar conductor; 15, 16 plating film; 20 carrier; 21 resin layer; 22 metal film; 31 first component; 32, 32i second component; 33, 34, 35, 36, 37, 37d, 38, 39a, 39b component; 41 first-surface-side wiring layer; 41e metal film; 42 second-surface-side wiring layer; 51 first-surface-side outer resin layer; 52 second-surface-side outer resin layer; 401, 402, 403, 404, 405, 406 interposer; 501, 502, 503, 504 coreless substrate

1. An interposer having a first surface as a mounting surface, and a second surface where an object is to be mounted, the second surface being opposite to the first surface, the interposer comprising:
a first component included in the interposer and having an electrode directly exposed on the first surface or connected to the first surface via a conductor;
a second component arranged to overlap the first component on a second surface side of the first component and being in contact with the first component, included in the interposer, and having an electrode directly exposed on the second surface or connected to the second surface via a conductor; and
a sealing resin layer sealing the first component and the second component.

2. The interposer according to claim 1, wherein
in the first surface, a first-surface-side outer resin layer is arranged so as to cover the sealing resin layer, and a first-surface-side wiring layer is arranged between the first-surface-side outer resin layer and the sealing resin layer, and
electrical connection from the first component to the first surface is made via the first-surface-side wiring layer.

3. The interposer according to claim 1, wherein
in the second surface, a second-surface-side outer resin layer is arranged so as to cover the sealing resin layer, and a second-surface-side wiring layer is arranged between the second-surface-side outer resin layer and the sealing resin layer, and
electrical connection from the second component to the second surface is made via the second-surface-side wiring layer.

4. The interposer according to claim 1, wherein
the first component is an IC.

5. The interposer according to claim 1, wherein
the second component is a capacitor.

6. The interposer according to claim 1, wherein
the second component is an IC.

7. The interposer according to claim 1, wherein
the object is a coreless substrate.

8. The interposer according to claim 1, wherein
the second component is directly in contact with the first component.

9. The interposer according to claim 2, wherein
in the second surface, a second-surface-side outer resin layer is arranged so as to cover the sealing resin layer, and a second-surface-side wiring layer is arranged between the second-surface-side outer resin layer and the sealing resin layer, and
electrical connection from the second component to the second surface is made via the second-surface-side wiring layer.

10. The interposer according to claim 2, wherein
the first component is an IC.

11. The interposer according to claim 3, wherein
the first component is an IC.

12. The interposer according to claim 2, wherein
the second component is a capacitor.

13. The interposer according to claim 3, wherein
the second component is a capacitor.

14. The interposer according to claim 4, wherein
the second component is a capacitor.

15. The interposer according to claim 2, wherein
the second component is an IC.

16. The interposer according to claim 3, wherein
the second component is an IC.

17. The interposer according to claim 4, wherein
the second component is an IC.

18. The interposer according to claim 2, wherein
the object is a coreless substrate.

19. The interposer according to claim 3, wherein
the object is a coreless substrate.

20. The interposer according to claim 4, wherein
the object is a coreless substrate.
